(19) United States
(12) Patent Application Publication
(10) Pub. No.: US 2005/0063212 A1
(43) Pub. Date: Mar. 24, 2005

(54) Reference circuit implemented to reduce the degradation of reference capacitors providing reference voltages for 1T1C FeRAM devices

(76) Inventors: Michael Jacob, Kanagawa-ken (JP); Norbert Rehm, Kanagawa-ken (JP); Hans-Oliver Joachim, Kanagawa-ken (JP); Joerg Wohlfahrt, Kanagawa-ken (JP)

Correspondence Address: FISH & RICHARDSON, PC, 12390 EL CAMINO REAL, SAN DIEGO, CA, 92130-2081, US

(21) Appl. No.: 10/665,401

(22) Filed: Sep. 18, 2003

(51) Int. Cl. G11C 11/22

(52) U.S. Cl. 365/145

(57) ABSTRACT

A semiconductor memory comprises a first capacitor for storing digital data connecting a cell plate line to a first bit-line through a first select transistor. The first select transistor is activated through a connection to a word line. At least one reference capacitor provides a reference voltage to a reference bit-line. A sense amplifier connected to the first and reference bit-lines measures a differential read signal on the first and reference bit-lines. A toggle flip flop alternately changes the polarization of charge stored on the reference capacitors.

### FIELD OF THE INVENTION

The present invention relates to the implementation of highly reliable reference voltage circuits for FeRAM memory cells.

### BACKGROUND OF THE INVENTION

In semiconductor memories, reliability issues have become more complicated with increasing memory sizes, smaller feature sizes and lower operating voltages. It has become more important to understand the cell signal sensing operation, the signal of memory cells and the limiting factors.

A design challenge for 1T1C (one-transistor one-capacitor per memory cell) FeRAM (Ferroelectric Random Access Memory) devices is the establishment of the reference voltage, which is complicated by the ferroelectric capacitor being a non-linear, hysteretic circuit element. Approaches include averaging the charge of one switching and one non-switching ferroelectric capacitor, using a non-switched ferroelectric capacitor, using a “dummy” reference capacitor (e.g. MOS capacitor), or using a direct reference voltage supply. All of these solutions have advantages and disadvantages.

Use of “dummy” reference capacitors or direct reference voltage sources has the advantage of enabling the implementation of a 1T1C signal margin test mode by variation of the “dummy” plate voltage or by variation of the direct reference voltage. However, designs using the “dummy” reference capacitors or direct reference voltage sources require large signal margins. This is because the temperature behavior of the “dummy” reference capacitors and direct reference voltage sources, along with the response to changes or deviations in the manufacturing process, may be different from those of the ferroelectric capacitors of the memory cell.

The use of ferroelectric reference capacitors has the advantage of being “self-adjusted” to manufacturing deviations and temperature changes.

FIG. 1 shows a general memory chip 102 configuration for providing a reference voltage for an FeRAM memory cell 101 having a 1T1C configuration. The 1T1C configuration utilizes one transistor and one capacitor per bit. The read signal of a ferroelectric cell capacitor on a bit-line BL 103 of a FeRAM memory cell 101 is compared to a reference signal on a reference bit-line BLr 107 generated by a reference voltage generation circuit 105. A differential read signal on the bit-line pair 103, 107 is evaluated by a connected sense amplifier 109.

FIG. 2 shows the details of a prior-art FeRAM circuit 301 including the circuit for generating the reference voltage 105 and the 1T1C memory cell 101 of FIG. 1. Also shown is a second 1T1C cell 303. The reference voltage from the circuit 105, along with the outputs from the outputs from the memory cells 101 and 303, are fed to the sense amplifier 109 and also a sense amplifier 305. The reference voltage is created by averaging a charge Qsw on a switching ferroelectric reference capacitor 307 with a charge Qnsw on a non-switching ferroelectric reference capacitors 309 (see the paper by D. Jung et al., IEDM Digest of Technical Papers, p. 279, 1999 for additional details). Here “switching” means that the polarization of the capacitor is changed during each access cycle.

FIG. 3 shows the timing for the reference voltage circuit of FIG. 2. A reference word line signal WLr is applied to gates of transistors 311 and 313 to provide a path between the ferroelectric reference capacitors 307, 309 and the reference bit-lines BLr0 and BLr1. At t0 the reference plate line (with potential PLr) is activated. The potential PLr charges the reference bit-lines BLr0 and BLr1 through the ferroelectric reference capacitors Qsw and Qnsw as shown by the plot of the potential on BLr0/1. Due to differences between the polarization states of the ferroelectric reference capacitors 307, 309 the reference bit-lines charge to different potentials during the time the reference word line signal WLr is applied. At time t1 the reference word line signal WLr is deactivated and the signal BLreq (bit-line reference equal) is applied to a transistor 315 to electrically connect the reference bit-lines BLr0 and BLr1 through the transistor 315 thereby equalizing the potential of the two bit-lines by averaging their potentials. At time t2 the signal BLreq is deactivated, the signal WBr (write back reference) 320 is applied to the gates of transistors 317, 319 and the sense amplifier 109 is enabled. At that time, the bit-line BLn0 103 is charged by reading the memory cell 101 (the timing of the memory cell is not shown in the figure). From the time the sense amplifier 109 is activated, the timing is related to the timing of the 1T1C FeRAM cell 101. At time t3 the reference plate line (with potential PLr) is deactivated and a write-back reference signal WBr0 321 is applied to the transistor 317 to begin write back to the switched ferroelectric reference capacitor 307. Finally at time t4 write back ends by turning off the signals WBr0 and WBr.

While the type of reference circuit 105, as illustrated in FIG. 2, provides the advantage of being “self-adjusted” to manufacturing deviations and temperature changes, Jung points out in the above cited paper that the circuit is disadvantageously effected by severe fatigue and the resulting degradation because the reference capacitors experience more access cycles than do real memory cells. The cause of this degradation can be further understood with additional reference to FIG. 3. During each cycle the write-back reference signal WBr0 321 is applied to the ferroelectric reference capacitor 307 and during each cycle the charges Qsw and Qnsw are stored on the reference capacitors 307, 309 with the same polarity. This results in performance degrading static and dynamic imprint on the reference capacitors 307, 309. The ferroelectric reference capacitors 307, 309 end up having different aging characteristics than do the ferroelectric capacitors of the memory cells 101, 303, reducing the advantages of using ferroelectric capacitors for both the memory cells and reference circuit.

It would be desirable to provide a reference circuit utilizing ferroelectric reference capacitors to generate a reference voltage for use by a 1T1C FeRAM device wherein the reference circuit is implemented to prevent the degradation of the ferroelectric reference capacitors. In particular, it would be desirable to provide bi-directional cycling to reduce static and dynamic imprint of the of the ferroelectric reference capacitor.

### SUMMARY OF THE INVENTION

The prior-art reference circuit is modified using a toggle flip flop to reduce the degradation of the reference circuit ferroelectric reference capacitors of the semiconductor memory chip. The semiconductor memory comprises a first capacitor for storing digital data connecting a cell plate line to a first bit-line through a first select transistor. The first select transistor is activated through a connection to a word line. At least one reference capacitor provides a reference voltage to a reference bit-line. A sense amplifier connected to the first and reference bit-lines measures a differential read signal on the first and reference bit-lines. A toggle flip flop alternately changes the polarization of charge stored on the reference capacitors.

### BRIEF DESCRIPTION OF THE FIGURES

Further preferred features of the invention will now be described for the sake of example only with reference to the following figures, in which:

FIG. 1 shows a prior-art memory chip circuit configuration for providing a reference voltage for an FeRAM memory cell having a 1T1C configuration.

FIG. 2 shows a prior-art implementation of the memory chip a of FIG. 1 including 1T1C memory cell circuits, sense amplifiers and a circuit for generating the reference voltage.

FIG. 3 shows the timing for the reference voltage circuit of FIG. 2.

FIG. 4 (a) shows a toggle flip flop and write back outputs of the present invention.

FIG. 4 (b) shows the timing of the signals produced by the toggle flip flop of FIG. 4 (a).

FIG. 5 shows a more detailed view of an embodiment of the toggle flip flop and write back outputs of FIG. 4 (a).

FIG. 6 shows the timing for a reference voltage circuit of FIG. 2 incorporating the toggle flip flop and write back outputs of the present invention.

FIG. 7 shows a chain FeRAM architecture

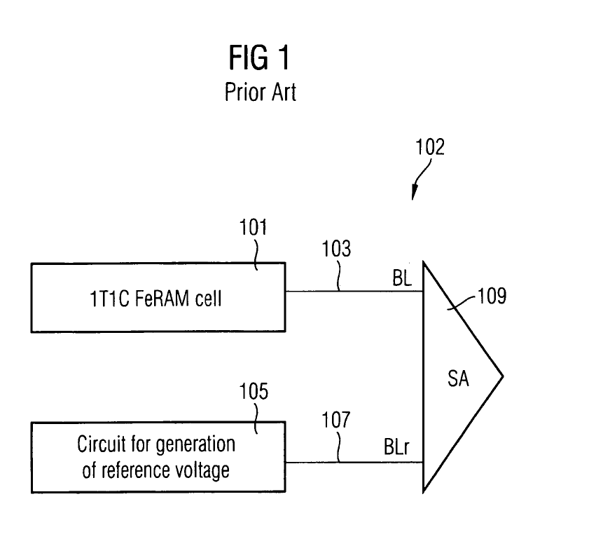

### DETAILED DESCRIPTION OF THE EMBODIMENTS

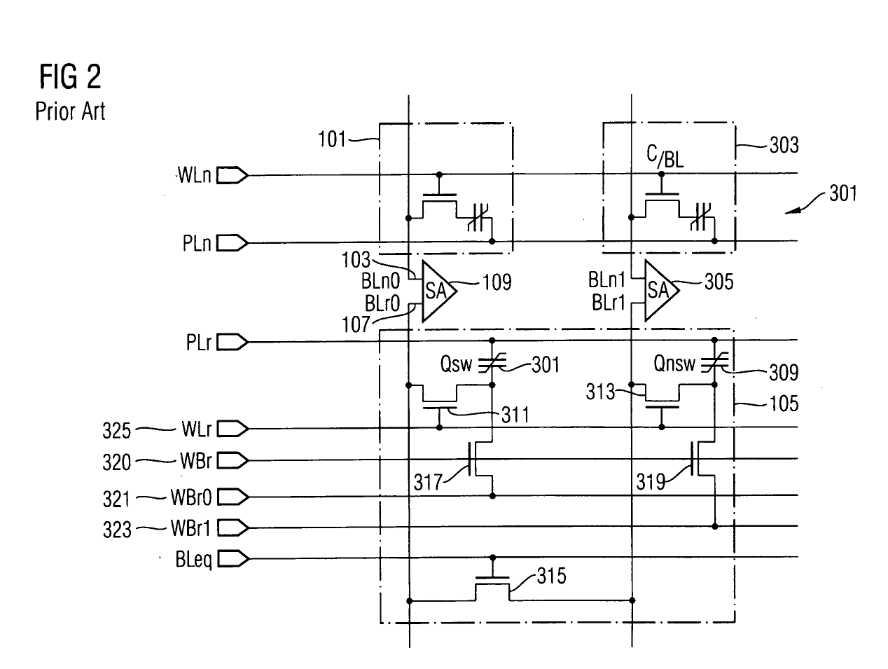

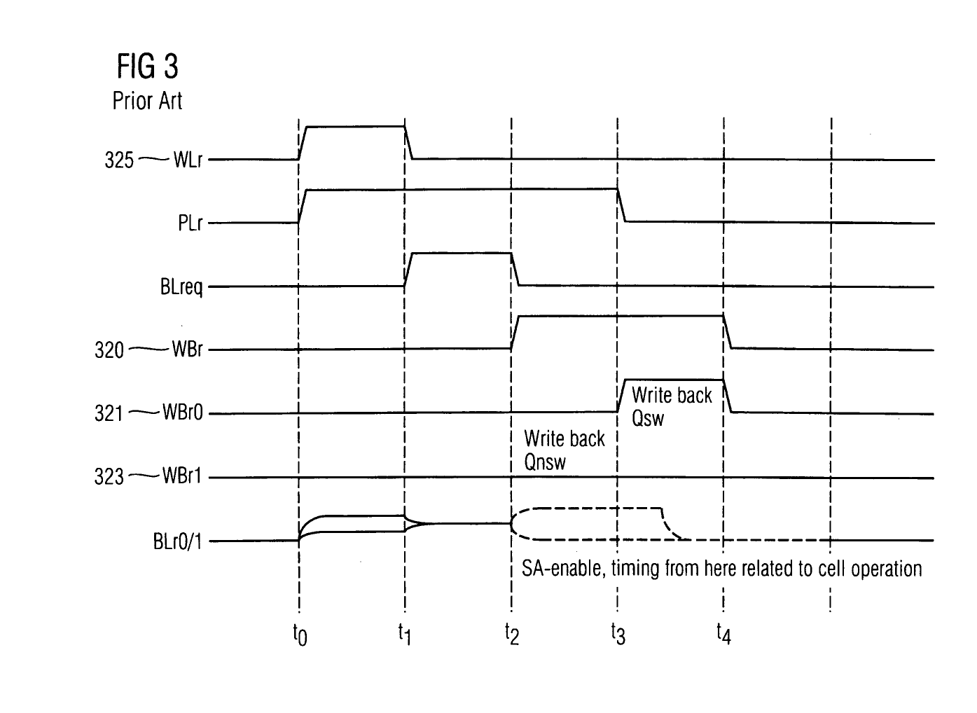

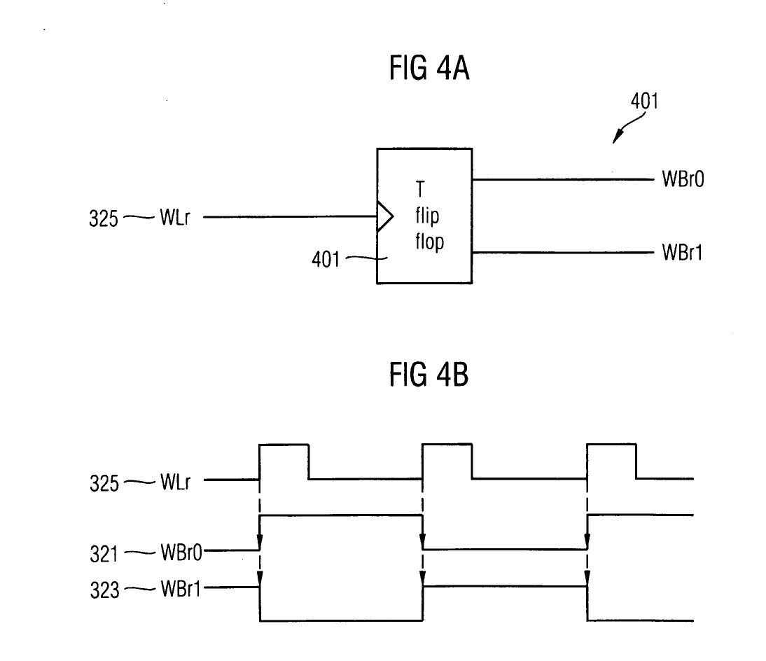

The prior-art reference circuit of FIG. 2 is modified using the toggle flip flop 401 of FIG. 4 (a) to reduce the degradation of the reference circuit 105 ferroelectric reference capacitors 307, 309. The reference word line signal WLr 325, in addition to triggering the transistors 311, 313, is also used to trigger the toggle flip flop 401. The toggle flip flop 401 alternately changes the signs of the stored polarization of both of the ferroelectric reference capacitors 307, 309. For each of the following access cycles, the ferroelectric reference capacitors 307, 309 are toggled between being charged to Qsw and being charged to Qnsw using the reference write back signals 321, 323 as illustrated by FIG. 4 (b).

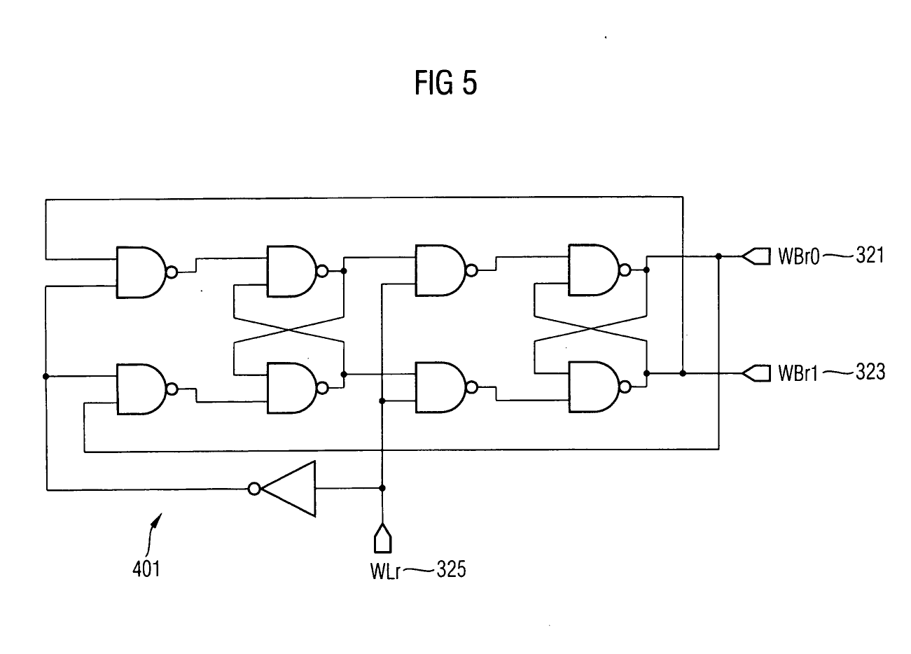

FIG. 5 shows an embodiment using NAND gates to implement the toggle flip flop and write back outputs of FIG. 4 (a).

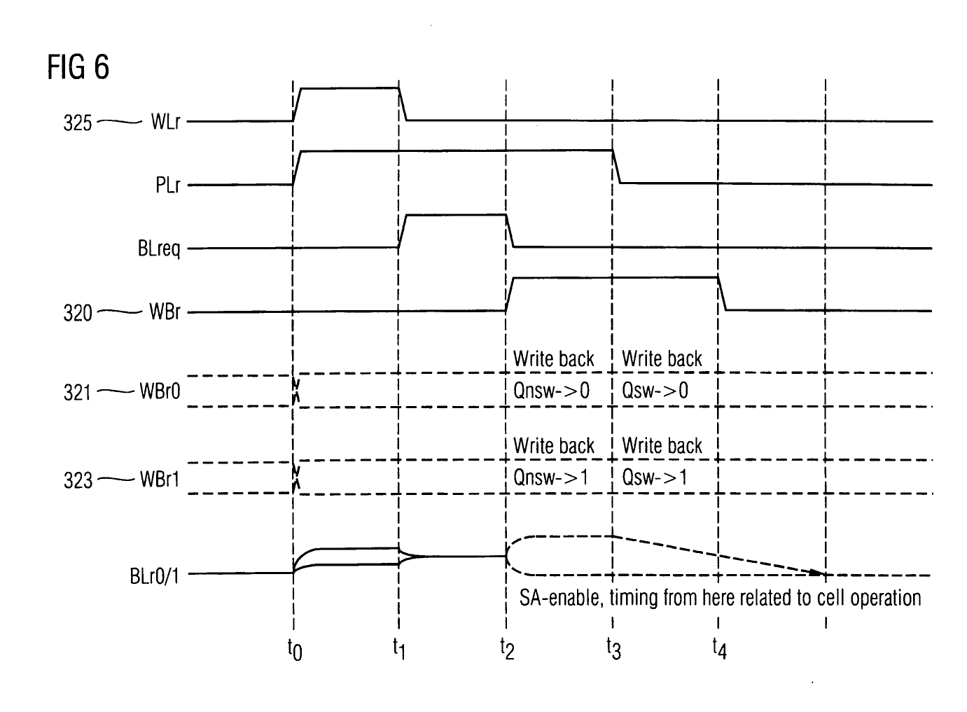

FIG. 6 shows the timing for a reference voltage circuit of FIG. 2 incorporating the toggle flip flop 401 and write back outputs 321, 323 of the present invention. As can be seen, the write back signals 321, 323 alternate between Qnsw and Qsw. In each cycle, one of the capacitors is switching while the other capacitor is non-switching. In subsequent cycles the switching capacitor becomes non-switching and vise versa. After t0, one BLr is charged to a higher potential (“switching capacitor”) and the other is charged to a lower potential (“non-switching capacitor”). After t1 both of the signals are equalized.

While in the examples the toggle flip flop 401 is shown as being triggered by the reference write line signal 325, other signals can be used as the trigger signal.

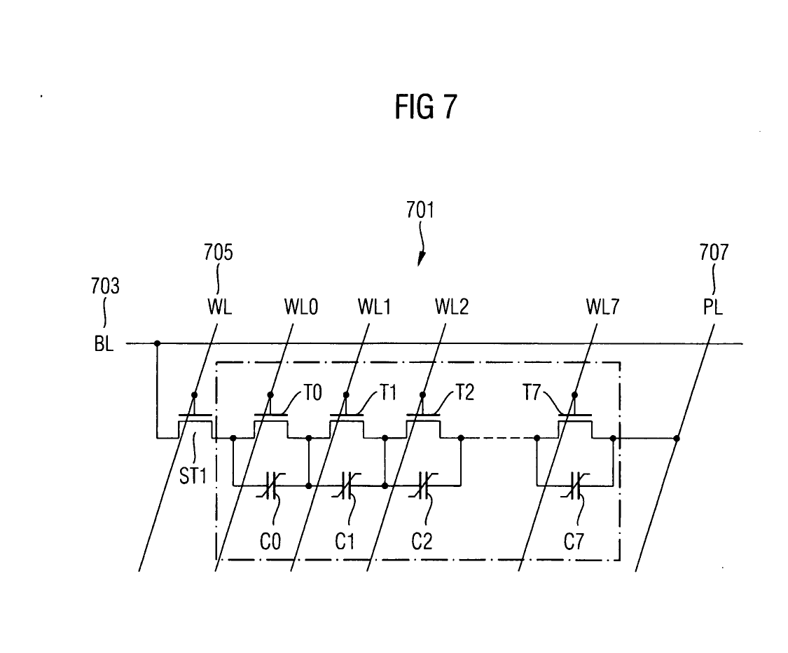

In the invention the ferroelectric reference capacitors 307, 309 or memory capacitors of FIG. 2 can each be replaced by multiple cells in a chain FeRAM architecture. The single ferroelectric capacitors of the architecture of FIG. 2 can thereby each be replaced by a chain of ferroelectric capacitors parallel to the write line and in series with each other. FIG. 7 shows one such chain FeRAM architecture 701. In this figure, eight transistors T0 to T7 (other numbers of transistors in other embodiments) are connected in series, and ferroelectric capacitors are each connected between a source and a drain of a corresponding one of the transistors to constitute a cell array block. The cell array block has one end connected to a bit line BL via a selection gate transistor ST1 and the other end connected to a plate line PL via a selection gate transistor ST2 (or directly). When replacing the capacitor 307 of FIG. 2 with the chain FeRAM 701, the bit line BL 703 is the bit line BLr0 107 and the selection gate transistor ST1 serves as the transistor 311 switched by a word line WL 705 (also referred to as a block select line because it selects the entire block of the chain FeRAM architecture) which is the word line WLr 325. The transistor ST1 serves to connect the plate line 707 to the bit line 703 through the ferroelectric capacitors C0-C7. The plate line 707 in FIG. 7 is the reference plate line of FIG. 2.

The transistors T0 to T7 have their gates connected to word lines WL0 to WL7, respectively. Specifically, the word lines WL0 to WL7 and the word line WL 705 are configured by continuously forming corresponding gate electrodes between a plurality of other cell array blocks (not shown). The chain FeRAM architecture is advantageous in that the unit cell area can be reduced by sharing a diffusion layer of the adjacent transistor within the cell array block; theoretically, these memories can achieve 4F² (F denotes a minimum size). Further, the area occupied by peripheral circuits can be reduced compared to ordinary ferroelectric memories, thereby reducing the chip size and costs.

The chain FeRAM architecture also has an excellent characteristic that the plate line PL 707 connected to the other end can be formed of the diffusion layer formed outside the cell array and thus has low resistance, whereby drivers are not required to have high performance. The chain FeRAM architecture can thus operate faster than ordinary ferroelectric memories.

As an example of the function of the chain FeRAM architecture 701, the ferroelectric capacitors of each chain connect the plate line to the bit line through the select transistor ST1 which is activated. The transistor T1 is also activated through a connection to the word line 705 and transistor T2 is deactivated while all the others T0, T1 and T3 remain activated.

The toggle flip flop can be on the memory chip 301 or can be off-chip.

In all of the above embodiments the described components, including the resistors and the transistors can be formed on the same die. Also, the term “connected” as used in the present disclosure does not imply that connected components must be in direct physical contact. Rather, the components need only be electrically connected.

Thus, although the invention has been described above using particular embodiments, many variations are possible within the scope of the claims, as will be clear to a skilled reader.

1. A semiconductor memory, comprising:
a first capacitor for storing digital data connecting a cell plate line to a first bit-line through a first select transistor, the first select transistor activated through a connection to a word line;
at least one reference capacitor for providing a reference voltage to a reference bit-line;
a sense amplifier connected to the first and reference bit-lines for measuring a differential read signal on the first and reference bit-lines; and
a toggle flip flop for alternately changing polarization of charge stored on the at least one reference capacitor.

2. The semiconductor memory of claim 1, wherein the at least one reference capacitor includes two reference capacitors, each one alternating between serving as a switching reference capacitor and a non-switching reference capacitor.

3. The semiconductor memory of claim 2, wherein the reference capacitors are ferroelectric capacitors.

4. The semiconductor memory of claim 3, wherein the first capacitor is also a ferroelectric capacitor.

5. The semiconductor memory of claim 1, wherein the toggle flip flop is comprised of NAND gates.

6. The semiconductor memory of claim 2, wherein the toggle flip flop alternately changes the polarization of the charge stored on the at least one reference capacitor by toggling write back signals supplied to the two reference capacitors.

7. The semiconductor memory of claim 6, wherein the charges on the two reference capacitors are averaged to supply the reference voltages to the sense amplifier.

8. The semiconductor memory of claim 1, wherein the first capacitor for storing digital data is part of a 1T1C memory cell.

9. The semiconductor memory of claim 1, wherein the at least one reference capacitor is part a cell also including a transistor, and wherein multiple such cells are connected in parallel to connect the cell plate line to the first bit-line through the first select transistor.
